(19) United States
(12) Patent Application Publication
(10) Pub. No.: US 2007/0247924 A1
(43) Pub. Date: Oct. 25, 2007

(54) Methods for erasing memory devices and multi-level programming memory device

(76) Inventors: Wei Zheng, Santa Clara, CA (US); Meng Ding, Sunnyvale, CA (US)

Correspondence Address: INGRASSIA FISHER & LORENZ, P.C., 7150 E. CAMELBACK, STE. 325, SCOTTSDALE, AZ, 85251, US

(21) Appl. No.: 11/399,158

(22) Filed: Apr. 6, 2006

(51) Int. Cl. G11C 16/04; G11C 11/34

(52) U.S. Cl. 365/185.29; 365/185.18

(57) ABSTRACT

A memory includes a first charge storage region spaced apart from a second charge storage region by an isolation region. Techniques for erasing a memory are provided in which electrons are Fowler-Nordheim (FN) tunneled out of at least one of the charge storage regions into a substrate to erase the at least one charge storage region of the memory. Other techniques are provided for programming a single charge storage region at multiple different levels or states.

### FIELD OF THE INVENTION

The present invention generally relates to memory devices, and more particularly relates to techniques for erasing and programming a dual-bit memory device.

### BACKGROUND OF THE INVENTION

Flash memory is a type of electronic memory media that can hold its data in the absence of operating power. Flash memory can be programmed, erased, and reprogrammed during its useful life (which may be up to one million write cycles for typical flash memory devices). Flash memory is becoming increasingly popular as a reliable, compact, and inexpensive nonvolatile memory in a number of consumer, commercial, and other applications. As electronic devices get smaller and smaller, it becomes desirable to increase the amount of data that can be stored per unit area on an integrated circuit memory cell, such as a flash memory unit.

One conventional flash memory technology is based upon a memory cell that utilizes a charge trapping dielectric cell that is capable of storing two bits of data. Recently, non-volatile memory designers have recently designed memory circuits that utilize two charge storage regions to store charge within a single silicon nitride layer. This type of non-volatile memory device is known as a dual-bit Flash electrically erasable and programmable read-only memory (EEPROM), which is available under the trademark MIRRORBIT™ from Spansion, Inc., Sunnyvale, Calif. In such an arrangement, one bit can be stored using a first charge storing region on one side of the silicon nitride layer, while a second bit can be stored using a second charge storing region on the other side of the same silicon nitride layer. For example, a left bit and right bit can be stored in physically different areas of the silicon nitride layer, near left and right regions of each memory cell, respectively. In comparison to a conventional EEPROM cell, a dual-bit memory cell can store twice as much information in a memory array of equal size.

Such a dual-bit memory cell can be programmed using hot electron injection techniques. FIG. 1 is a cross-sectional view of the conventional dual-bit memory cell 50 during a Channel Hot Electron (CHE) injection program operation. The memory cell 50 has a dual bit (bit1, bit2) architecture that allows twice as much storage capacity as a conventional EEPROM memory device.

The memory cell 50 comprises an oxide-nitride-oxide (ONO) stack 62-64, and a gate 68 disposed between a first buried junction region 60 and a second buried junction region 61 which reside in a substrate 54. In the implementation shown, the substrate 54 is a P-type semiconductor substrate 54 having the first buried junction region 60 and the second buried junction region 61 formed within substrate 54 in self-alignment with the memory cell 50. First buried junction region 60 and second buried junction region 61 are each formed from an N+ semiconductor material. A first insulator layer 62, a charge storage layer 64, and a second insulator layer 66 can be implemented using an oxide-nitride-oxide (ONO) configuration. In this case, a nitride charge storage layer 64 capable of holding a charge is sandwiched between two oxide insulator layers 62, 66. The first insulator layer 62 is disposed over the substrate 54, the silicon dioxide or nitride charge storage layer 64 is disposed over the first insulator layer 62, the second insulator layer 66 is disposed over the charge storage layer 64, and the polysilicon control gate 68 is disposed over the second insulator layer 66. To produce an operable memory device, a first metal silicide contact (not shown) can be disposed on substrate 54, and the control gate 66 can be capped with a second metal silicide contact (not shown).

Memory cell 50 can store two data bits: a left bit represented by the circle (bit 1); and a right bit represented by the circle (bit 2). In practice, memory cell 50 is generally symmetrical, thus first buried junction region 60 and second buried junction region 61 are interchangeable. In this regard, first buried junction region 60 may serve as the source region with respect to the right bit (bit 2), while second buried junction region 61 may serve as the drain region with respect to the right bit (bit 2). Conversely, second buried junction region 61 may serve as the source region with respect to the left bit (bit 1), while first buried junction region 60 may serve as the drain region with respect to the left bit (bit 1). A threshold voltage exists between the control gate 66 and the substrate 54 to prevent leakage during functioning of the device.

As shown in FIG. 1, an exemplary programming process, sometimes referred to as Channel Hot Electron (CHE) injection, can be used to program bit 2 of the charge storage layer 64 of the mirror bit cell 50. In this exemplary implementation, bit 2 of the memory cell 50 can be programmed by grounding or floating the source 60 at a neutral voltage (e.g., approximately zero volts), applying a relatively high voltage to the drain 61 (e.g., applying a voltage to the drain 61 between 3.5 volts and 5.5 volts), and applying a relatively high voltage (e.g., between 7 and 10 volts) to the gate 68. Setting the drain 61 at a relatively higher voltage than the source 60 creates a lateral field which accelerates electrons from the source 60 to the drain 61. Setting the gate 68 at a relatively high voltage sets up a strong vertical electrical field. When the electrons gain enough energy near the drain region 61, the strong vertical field pulls the electrons across the tunnel oxide layer 62 into bit 2 of the nitride charge storage layer 64. These electrons are then trapped in the charge storage layer 64. (e.g., charge gets trapped in the nitride (an insulator) and does not move). Absence of a localized charge near the drain 61 area (at bit 2) can be interpreted as a logical one, and presence of a localized charge near the drain 61 area (at bit 2) can be interpreted as a logical zero (or vice versa). It will be appreciated that while in the following example the buried junction regions 60, 61 can be referred to as a source 60 and a drain 61, if biased in the opposite manner by switching the bias voltages on the buried junction regions 60, 61, the buried junction regions 60, 61 can also function as a drain and a source, respectively. This allows charge to be stored (or not stored) at bit 1 on the other side of the charge storage layer 64.

As noted above, the memory cell is capable of storing two bits (bit1, bit2). When the charge storage region on the right hand side of the charge storage layer 164 (referred to hereafter at the “programmed cell” or “normal bit 2”) is programmed up to store some electrons, and the charge storage region on the left hand side is unprogrammed (referred to hereafter at the “unprogrammed cell” or “complimentary bit 1”), the threshold voltage (V_{T}) of the complimentary bit 1 may be disturbed, when the normal bit 2 is programmed, the threshold voltage (V_{T}) of the complimentary bit 1 will be pulled up or increase even though the complimentary bit 1 has not been programmed (e.g., does not store electrons). In other words, the threshold voltage (V_{T}) at the complimentary bit 1 shifts somewhat (e.g., increases slightly) because the normal bit 2 has been programmed up. This phenomenon is sometimes referred to as a “complimentary bit 1 disturbance.” This disturbance can limit the threshold voltage (V_{T}) window between the normal bit 2 and the complimentary bit 1 (for example, to about 2 volts) and can not be further increased.

The complimentary bit 1 disturbance effectively limits a V_{T} difference or “window” between the programmed cell (e.g., normal bit 2) and the unprogrammed cell (e.g., unprogrammed complimentary bit 1) to approximately 2 volts. Further, programming the normal bit to even higher V_{T} level will only result in a higher complimentary bit V_{T} and cannot further increase the V_{T} difference between the two bits. This complimentary bit disturbance makes it difficult or impossible to implement a multi-level cell that can be programmed at multiple different levels. It would be desirable to alleviate this issue.

FIG. 2 is a cross-sectional view of the structure of the conventional dual-bit memory cell 50 during a band-to-band channel hot hole (CHH) erasing operation. To erase bit 2 of the memory cell 50, a medium positive bias voltage (e.g., between 4 and 7 volts) can be applied to the drain 61, the source 60 can be at ground or floating, and a relatively high negative bias voltage (e.g., between −5 and −9 volts) can be applied to the gate 68. Biasing the gate 68 and drain 61 in this manner this causes band-to-band hole generation and injection from the drain 61 area towards the gate 68. The holes recombine (e.g., neutralize) electrons that are trapped at bit 2 in the portion of the charge storage region 64 located near the drain 61. This effectively erases bit 2. Similarly, bit 1 could be erased by swapping the bias voltages applied to the drain 61 and source 60 (e.g., a medium positive voltage (e.g., between 4 and 7 volts) can be applied to the source 60, the drain 61 can be at ground or floating, and a relatively high negative bias voltage (e.g., between −5 and −9 volts) can be applied to the gate 68). Biasing the gate 68 and source 60 in this manner this causes band-to-band hole generation or injection from the source 60 area towards the gate 68. The holes recombine (e.g., neutralize) electrons that are trapped at bit 1 in the portion of the charge storage region 64 located near the source 60. This effectively erases bit 1.

Notwithstanding these advances, it would be desirable to provide improved techniques for erasing and/or programming a dual-bit memory cell. Furthermore, other desirable features and characteristics of the present invention will become apparent from the subsequent detailed description of the invention and the appended claims, taken in conjunction with the accompanying drawings and this background of the invention.

### SUMMARY

Techniques for erasing and programming a memory are provided.

According to one embodiment, techniques are provided for erasing a memory which includes a first charge storage region spaced apart from a second charge storage region by an isolation region. Electrons are tunneled out of at least one of the charge storage regions into a substrate to erase the at least one charge storage region. The charge storage regions can be physically and electrically separated by the isolation region.

According to another embodiment, techniques for programming a single charge storage region at multiple different levels or states are provided.

### BRIEF DESCRIPTION OF THE DRAWINGS

The present invention will hereinafter be described in conjunction with the following drawing figures, wherein like numerals denote like cells, and wherein

FIG. 1 is a cross-sectional view of the conventional dual-bit memory cell during a Channel Hot Electron (CHE) injection programming operation;

FIG. 2 is a cross-sectional view of the structure of the conventional dual-bit memory cell during a band-to-band channel hot hole (CHH) erasing operation;

FIG. 3 is a cross-sectional view of a portion of a dual-bit memory cell in accordance with an exemplary embodiment of the present invention;

FIG. 4 is a simplified diagram of a plurality of dual bit memory cells arranged in a memory cell array; and

FIG. 5 is a cross-sectional view of the portion of the dual-bit memory cell which illustrates a Fowler-Nordheim (FN) erasing operation in accordance with an exemplary embodiment of the present invention.

### DETAILED DESCRIPTION AN EXEMPLARY EMBODIMENT

The following detailed description of the invention is merely exemplary in nature and is not intended to limit the invention or the application and uses of the invention. Furthermore, there is no intention to be bound by any theory presented in the preceding background of the invention or the following detailed description of the invention.

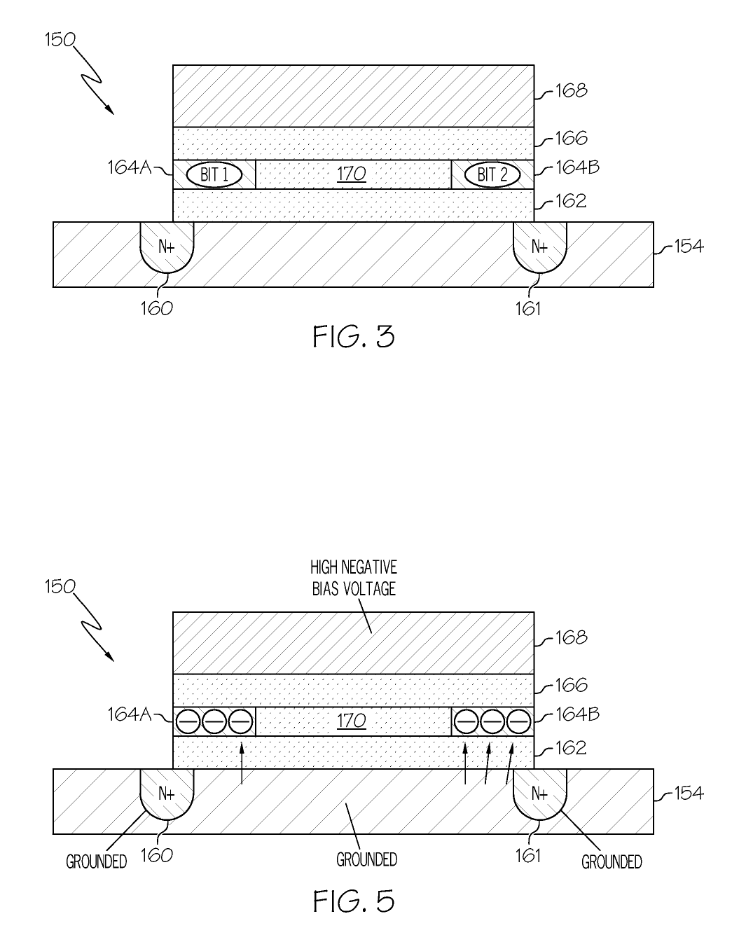

FIG. 3 is a cross-sectional view of a portion of a dual-bit memory cell 150 in accordance with an exemplary embodiment of the present invention. The mirror-bit memory cell 150 comprises a substrate 154 having a first buried junction region 160 and a second buried junction region 161 formed within substrate 154 in self-alignment with the memory device 150, a first insulator layer 162 disposed over the substrate 154, a pair of charge storage layers 164A, 164B each being disposed over the first insulator layer 162, an isolation region 170 disposed between charge storage regions 164A, 164B, a second insulator layer 166 disposed over the charge storage regions 164A, 164B, and the isolation region 170, and a control gate 168 disposed over the second insulator layer 166. A first metal silicide contact (not shown) can be disposed on substrate 154, and the control gate 166 can be capped with a second metal silicide contact (not shown).

The charge storage regions 164A, 164B are disposed, for example, between the first insulator layer 162 and the second insulator layer 164. The charge storage regions 164A, 164B are physically and electrically separated by the isolation region 170 which is disposed between the charge storage regions 164A, 164B. In one implementation, the control gate 168 may comprise polysilicon, the charge storage regions 164A, 164B may comprise silicon-rich nitride, polysilicon, or other equivalent charge trapping materials, and the isolation region 170 may comprise, for example, an oxide. Thus, the dielectric stack between the substrate 154 and control gate 168 may comprise, for example, an oxide-silicon rich nitride-oxide (ORO) stack, an oxide-polysilicon-oxide (OPO) stack, or an oxide-silicon rich nitride-Poly-silicon rich nitride-oxide (ORPRO) stack, etc.

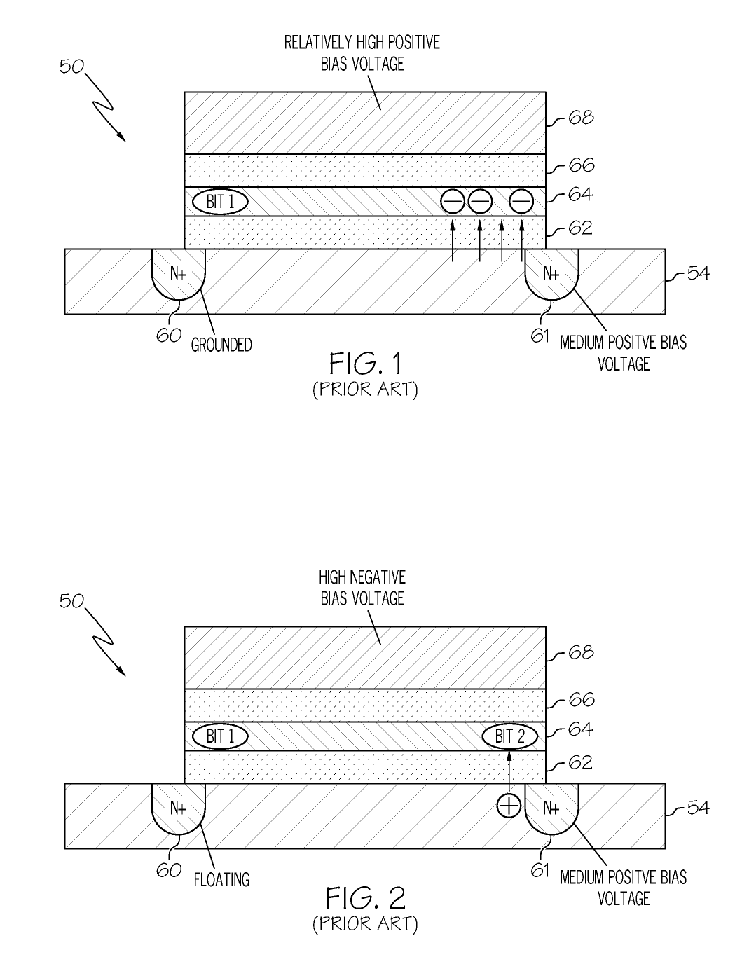

Physical separation of the charge storage regions 164 A, B via the isolation region 170 allows the size of a threshold voltage (V_{T}) window between a programmed cell (e.g., normal bit 2 at charge storage region 164 B) and an unprogrammed cell (e.g., unprogrammed complimentary bit 1 at charge storage region 164 A) to be expanded or increased. This allows the complimentary bit 1 disturbance issue to be greatly reduced and virtually eliminated. For instance, in contrast the memory cell architecture 50 of FIG. 1, the memory cell architecture 150 of FIG. 3 can allow the V_{T} window between the programmed cell (e.g., normal bit 2) and the unprogrammed cell (e.g., unprogrammed complimentary bit 1) to be increased to approximately 4.5 volts or more.

Because complimentary bit 1 disturbance is no longer an issue in memory cell architecture 150 of FIG. 3, the memory cell 150 can be programmed at multiple levels. In other words, the memory cell 150 is a multi-level cell (MLC). The wider the V_{T} window between the programmed cell (e.g., normal bit 2) and the unprogrammed cell (e.g., unprogrammed complimentary bit 1) allows for intermediate states to be provided. For example, when the programmed cell (e.g., normal bit 2) is programmed up to 5 volts, the V_{T} unprogrammed cell (e.g., unprogrammed complimentary bit 1) will remain very close to zero volts. As such, a certain cell can also be programmed at different levels, for example, to 2 volts, 3 volts, 4 volts or 5 volts. These different levels allow different states to be stored in each charge storage region. For instance, the larger V_{T} window can allow two bits to be stored at the normal bit 2, and another two bits can be stored on at the complimentary bit 1 such that four bits can be stored in a single memory cell 150.

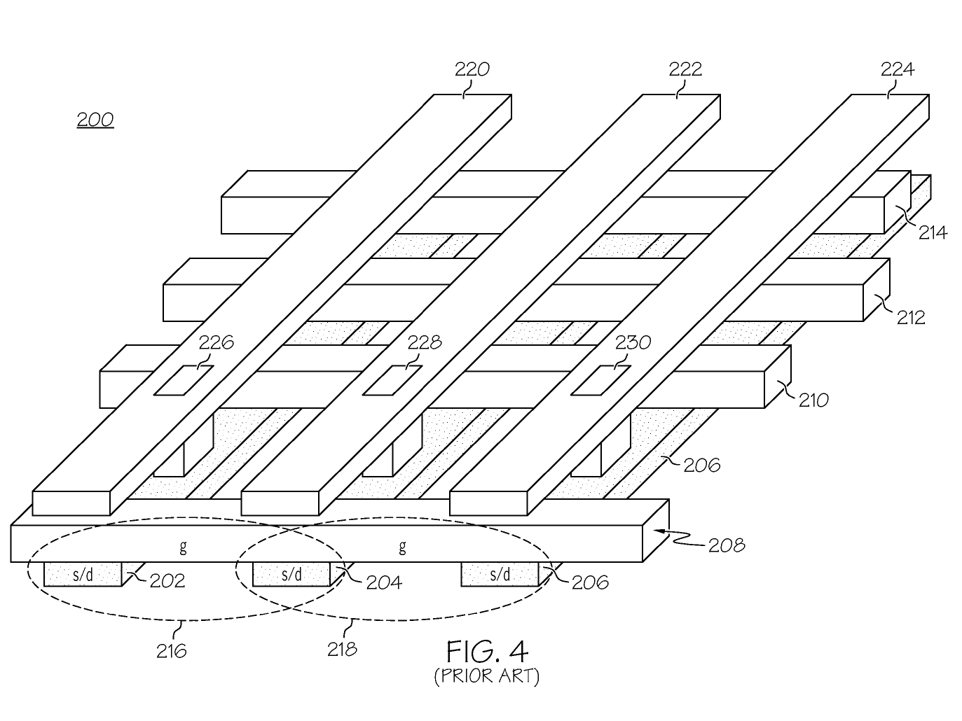

While a single dual bit memory cell 150 is illustrated in FIG. 3, it will be appreciated that any suitable number of the dual bit memory cells 150 could be used to form a memory array, as described below with reference to FIG. 4.

FIG. 4 is a simplified diagram of a plurality of dual bit memory cells arranged in accordance with a conventional array architecture 200 (a practical array architecture can include thousands of dual bit memory cells 50). Array architecture 200 includes a number of buried bit lines formed in a semiconductor substrate as mentioned above. FIG. 4 depicts three buried bit lines (reference numbers 202, 204, and 206), each being capable of functioning as a drain or a source for memory cells in array architecture 200. Array architecture 200 also includes a number of word lines that are utilized to control the gate voltage of the memory cells. FIG. 4 depicts four word lines (reference numbers 208, 210, 212, and 214) that generally form a crisscross pattern with the bit lines. Although not shown in FIG. 3, charge storage layer, such as an ORO or OPO stack, resides between the bit lines and the word lines. The dashed lines in FIG. 4 represent two of the dual bit memory cells in array architecture 200: a first cell 216 and a second cell 218. Notably, bit line 204 is shared by first cell 216 and second cell 218. Array architecture 200 is known as a virtual ground architecture because ground potential can be applied to any selected bit line and there need not be any bit lines with a fixed ground potential.

Control logic and circuitry (not shown) for array architecture 200 governs the selection of memory cells, the application of voltage to the word lines 208, 210, 212, 214, and the application of voltage to the bit lines 202, 204, 206 during conventional flash memory operations, such as: programming; reading; erasing; and soft programming. Voltage is delivered to the bit lines 202, 204, 206 using bit line contacts (not shown). FIG. 4 depicts three conductive metal lines (reference numbers 220, 222, and 224) and three bit line contacts (reference numbers 226, 228, and 230). For a given bit line, a bit line contact is used once every 16 word lines because the resistance of the bit lines is very high.

FN Erase Operation

FIG. 5 is a cross-sectional view of the portion of the dual-bit memory cell 150 which illustrates a Fowler-Nordheim (FN) erasing operation in accordance with an exemplary embodiment of the present invention.

To enable an FN erase operation, the charge storage regions 164 A, B of the cell 150 comprise silicon rich nitride or a similar material (e.g., such as polysilicon). According to one embodiment of the FN erase operation, a strong vertical field can set up through the stack by grounding the substrate 154, floating the source 160 and drain 161, and then applying a high negative to the control gate 168. According to an alternative embodiment, a strong vertical field can be created by applying a relatively high negative bias voltage (e.g., −8 to −10 volts) at the gate 168 and applying a positive bias voltage to the substrate 154.

When a strong vertical field is set up, electrons that are trapped in charge storage regions 164 A, B are ejected or pushed out of the charge storage regions 164 A, B into the substrate 154 allowing the memory cell 150 to be erased. Utilizing materials such as silicon rich nitride can allow an FN erase operation to be performed since electrons are more mobile in these materials since they have less charge trap density in comparison to other materials (e.g., nitride) in which the electrons fixed and less mobile. In essence, constructing the charge storage regions 164 A, B using materials such as silicon rich nitride makes it easier to push charge out of the charge storage regions 164 A, B. Attempting to apply the same FN erase operation to a memory cell implementing, for example, nitride charge storage regions would not work since the electrons could not be pushed out of the nitride charge storage regions.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of cells described in an exemplary embodiment without departing from the scope of the invention as set forth in the appended claims and their legal equivalents.

What is claimed is:

1. A method, comprising:
providing a memory comprising a first charge storage region spaced apart from a second charge storage region by an isolation region, wherein the charge storage regions comprise silicon rich nitride; and
Fowler-Nordheim (FN) tunneling electrons out of at least one of the charge storage regions into the substrate to erase the at least one charge storage region.

2. A method according to claim 1, wherein the memory further comprises a substrate and a gate, and wherein Fowler-Nordheim (FN) tunneling comprises:
grounding the substrate;
applying a voltage to the gate to push electrons from the at least one of the charge storage regions into the substrate.

4. A method according to claim 1, wherein the charge storage regions are physically and electrically separated by the isolation region disposed between the charge storage regions.

5. A semiconductor device, comprising:
a substrate;
an isolation region;
a first charge storage region comprising silicon rich nitride;
a second charge storage region comprising silicon rich nitride, wherein the second charge storage region is spaced apart from the first charge storage region by the isolation region; and
a gate,
wherein at least one of the charge storage regions is configured to be erased by injecting electrons into the substrate from the at least one of the charge storage regions by grounding the substrate and applying a voltage to the gate to inject electrons from at least one of the charge storage regions into the substrate.

6. A semiconductor device according to claim 5, wherein the charge storage regions are physically and electrically separated by the isolation region disposed between the charge storage regions.

7. A method, comprising:
providing a memory comprising a first charge storage region spaced apart from a second charge storage region by an isolation region, wherein the charge storage regions comprise polysilicon; and
Fowler-Nordheim (FN) tunneling electrons out of at least one of the charge storage regions into the substrate to erase the at least one charge storage region.

8. A method according to claim 7, wherein the memory further comprises a substrate and a gate, and wherein Fowler-Nordheim (FN) tunneling comprises:
grounding the substrate;
applying a voltage to the gate to push electrons from the at least one of the charge storage regions into the substrate.

9. A method according to claim 7, wherein the charge storage regions are physically and electrically separated by the isolation region disposed between the charge storage regions.

10. A semiconductor device, comprising:
a substrate;
an isolation region;
a first charge storage region comprising polysilicon;
a second charge storage region comprising polysilicon, wherein the second charge storage region is spaced apart from the first charge storage region by the isolation region; and
a gate,
wherein at least one of the charge storage regions is configured to be erased by injecting electrons into the substrate from the at least one of the charge storage regions by grounding the substrate and applying a voltage to the gate to inject electrons from at least one of the charge storage regions into the substrate.

11. A semiconductor device according to claim 10, wherein the charge storage regions are physically and electrically separated by the isolation region disposed between the charge storage regions.

12. A semiconductor device, comprising:
a substrate;
an isolation region;
a first charge storage region comprising silicon rich nitride, wherein the first charge storage region is configured to store a first bit and a second bit;
a second charge storage region comprising silicon rich nitride, wherein the second charge storage region is spaced apart from the first charge storage region by the isolation region, wherein the first charge storage region is configured to store a first complimentary bit 1 and a second complimentary bit 1, wherein the isolation region is configured to prevent disturbance of a second threshold voltage of the first and second complimentary bit 1 when the first and second bits are programmed, respectively.

13. A semiconductor device according to claim 12, wherein the charge storage regions are physically and electrically separated by the isolation region disposed between the charge storage regions.

14. A semiconductor device according to claim 12, wherein a threshold voltage (V_{T}) window between the first charge storage region and the second charge storage region is approximately 4.5 volts or more.

15. A semiconductor device according to claim 12, wherein the first charge storage region is programmable at multiple states with the first threshold voltage (V_{T}) between zero and five volts, while the second threshold voltage (V_{T}) at the second charge storage region remains at approximately zero volts.
